(19) United States
(12) Patent Application Publication
(10) Pub. No.: US 2026/0162944 A1
(43) Pub. Date: Jun. 11, 2026

(54) OUTER PERIPHERAL RING SET AND PLASMA PROCESSING APPARATUS

(71) Applicant: Kioxia Corporation, Tokyo (JP)

(72) Inventors: Masaki MAE, Yokkaichi Mie (JP); Hideo ETO, Yokkaichi Mie (JP)

(73) Assignee: Kioxia Corporation, Tokyo (JP)

(21) Appl. No.: 19/231,689

(22) Filed: Jun. 9, 2025

(30) Foreign Application Priority Data
Dec. 6, 2024 (JP) 2024-212989

(51) Int. Cl. H01J 37/32

(52) U.S. Cl. CPC H01J 37/32642; H01J 37/32568

(57) ABSTRACT

According to one embodiment, an outer peripheral ring set used in a plasma processing apparatus for processing a substrate, includes a first outer peripheral ring including a first annular portion that has a plurality of first slits, a second annular portion that faces the first annular portion at a predetermined distance, and a wall portion that connects an outer edge portion of the first annular portion and an outer edge portion of the second annular portion, and a second outer peripheral ring that is disposed on a surface of the first annular portion facing the second annular portion and has a plurality of second slits at positions overlapping the plurality of first slits in a vertical direction.

### CROSS-REFERENCE TO RELATED APPLICATIONS

This application is based upon and claims the benefit of priority from Japanese Patent Application No. 2024-212989, filed on Dec. 6, 2024; the entire contents of which are incorporated herein by reference.

### FIELD

Embodiments described herein relate generally to an outer peripheral ring set and a plasma processing apparatus.

### BACKGROUND

In a plasma processing apparatus for processing a substrate, a mechanism for containing plasma in the vicinity of the substrate may be used. The plasma containment mechanism includes, for example, an outer peripheral ring having a plurality of slits and surrounding the outer periphery of the substrate, and an adjustment plate facing the outer peripheral ring and having a separation distance from the outer peripheral ring adjusted.

However, as the plasma processing time elapses, the outer peripheral ring is worn out, and opening areas of the plurality of slits are expanded, so that it may be difficult to contain the plasma.

### BRIEF DESCRIPTION OF THE DRAWINGS

FIG. 1 is a cross-sectional view schematically illustrating an example of a configuration of a plasma processing apparatus according to a first embodiment;

FIGS. 2A and 2B are schematic views illustrating an example of a configuration of an outer peripheral ring according to the first embodiment;

FIG. 3 is a perspective cross-sectional view illustrating a state in which the outer peripheral rings according to the first embodiment overlap each other;

FIGS. 4A to 4D are schematic cross-sectional views of one side surface of the outer peripheral ring according to the first embodiment;

FIGS. 5A to 5C are schematic views illustrating an example of a configuration of an outer peripheral ring according to a modification example of the first embodiment;

FIGS. 6A and 6B are schematic views illustrating another example of the configuration of the outer peripheral ring according to the modification example of the first embodiment;

FIG. 7 is a schematic view illustrating still another example of the configuration of the outer peripheral ring according to the modification example of the first embodiment;

FIG. 8 is a cross-sectional view schematically illustrating an example of a configuration of a plasma processing apparatus according to a second embodiment;

FIGS. 9A to 9C are schematic views illustrating an example of a configuration of an outer peripheral ring according to the second embodiment;

FIGS. 10A and 10B are schematic views illustrating an example of the configuration of the outer peripheral ring according to the second embodiment;

FIG. 11 is a top view illustrating the entire configuration of the outer peripheral ring according to the second embodiment after a predetermined use time has elapsed;

FIGS. 12A and 12B are cross-sectional views of one side surface of the outer peripheral ring according to the second embodiment after a lapse of a predetermined use time;

FIGS. 13A and 13B are top views illustrating the entire configuration of the outer peripheral ring according to the second embodiment after a predetermined use time has elapsed;

FIGS. 14A to 14C are top views illustrating a state in which the outer peripheral ring according to the second embodiment is overlapped while changing the angle after a predetermined use time elapses;

FIGS. 15A and 15B are cross-sectional views of one side surface after the outer peripheral ring according to the second embodiment is reattached; and

FIG. 16 is a flowchart illustrating an example of a procedure of plasma processing in the plasma processing apparatus according to the second embodiment.

### DETAILED DESCRIPTION

An outer peripheral ring set according to an embodiment is an outer peripheral ring set used in a plasma processing apparatus for processing a substrate, and includes: a first outer peripheral ring including a first annular portion that has a plurality of first slits, a second annular portion that faces the first annular portion at a predetermined distance, and a wall portion that connects an outer edge portion of the first annular portion and an outer edge portion of the second annular portion; and a second outer peripheral ring that is disposed on a surface of the first annular portion facing the second annular portion and has a plurality of second slits at positions overlapping the plurality of first slits in a vertical direction.

Hereinafter, embodiments of the present invention will be described in detail with reference to the drawings. Note that the present invention is not limited by the following embodiments. In addition, constituent elements in the following embodiments include those that can be easily assumed by those skilled in the art or those that are substantially the same.

### First Embodiment

Hereinafter, a first embodiment will be described in detail with reference to the drawings.

### Configuration Example of Plasma Processing Apparatus

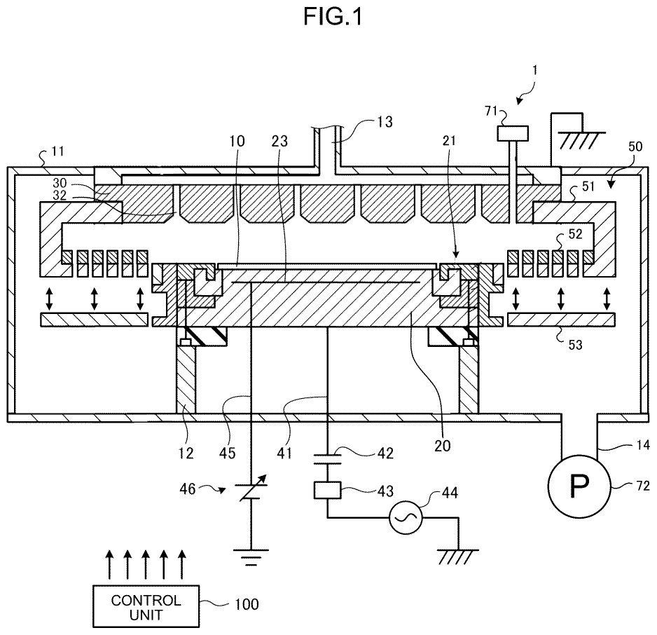

FIG. 1 is a cross-sectional view schematically illustrating an example of a configuration of a plasma processing apparatus 1 according to a first embodiment. The plasma processing apparatus 1 is configured as, for example, a reactive ion etching (RIE) apparatus that performs plasma etching processing on a wafer 10 as a substrate.

As illustrated in FIG. 1, the plasma processing apparatus 1 includes a processing container 11 in which the wafer 10 is processed. The processing container 11 is made of, for example, aluminum, and can be hermetically sealed.

A gas supply port 13 is provided in the vicinity of the upper portion of the processing container 11. A gas supply device (not illustrated) is connected to the gas supply port 13 through a pipe, and a processing gas used at the time of plasma processing is supplied thereto.

A shower head 30 functioning as an upper electrode is provided near the upper portion of the processing container 11 and below the gas supply port 13. The shower head 30 is provided with a plurality of gas flow paths 32 penetrating in the thickness direction of the plate. The processing gas supplied from the gas supply port 13 is introduced into the processing container 11 via the gas flow paths 32.

A wafer stage 20 is disposed below the shower head 30 so as to face the shower head 30. The wafer stage 20 horizontally supports the wafer 10 to be processed and functions as a lower electrode.

The wafer stage 20 is supported on a support portion 12 protruding in a cylindrical shape vertically upward from a bottom wall near the center of the processing container 11. The support portion 12 supports the wafer stage 20 so that the wafer stage faces the shower head 30 in parallel. In addition, the support portion 12 supports the wafer stage 20 so that the wafer stage is located near the center of the processing container 11 at a predetermined distance from the shower head 30. With such a structure, the shower head 30 and the wafer stage 20 constitute a pair of parallel plate electrodes.

A power supply line 41 for supplying radio frequency power is connected to the wafer stage 20. A blocking capacitor 42, a matching device 43, and a radio frequency power supply 44 are connected to the power supply line 41. The radio frequency power supply 44 supplies radio frequency power of a predetermined frequency to the wafer stage 20 during plasma processing. With such a configuration, the plasma processing apparatus 1 is configured as, for example, a lower application type plasma processing apparatus.

However, the plasma processing apparatus 1 may be configured as an upper application type plasma processing apparatus by connecting the power supply line 41 including the blocking capacitor 42, the matching device 43, the radio frequency power supply 44, and the like to the shower head 30 functioning as an upper electrode.

Alternatively, the plasma processing apparatus 1 may be configured as an upper-lower application type plasma processing apparatus by connecting the power supply line 41 including the blocking capacitor 42, the matching device 43, the radio frequency power supply 44, and the like to both the wafer stage 20 and the shower head 30.

The wafer stage 20 includes a chuck mechanism that electrostatically attracts the wafer 10, and also functions as an electrostatic chuck that electrostatically attracts the wafer 10.

The chuck mechanism includes a chuck electrode 23, a power supply line 45, and a power supply 46. The chuck electrode 23 is built in the wafer stage 20, and the power supply 46 is connected to the chuck electrode 23 via the power supply line 45. With such a mechanism, DC power is supplied from the power supply 46 to the chuck electrode 23, the upper surface of the wafer stage 20 is electrostatically charged, and the wafer 10 is attracted.

A focus ring 21 that covers the side surface and the peripheral edge portion of the wafer stage 20 is disposed in a peripheral edge portion of the wafer stage 20. The focus ring 21 adjusts the electric field so that the electric field is not deflected in the vertical direction perpendicular to the wafer surface at the peripheral edge portion of the wafer 10 when the wafer 10 is etched.

Outer peripheral rings 51 and 52 are provided between the focus ring 21 and the side wall of the processing container 11. The outer peripheral ring 51 has a C-shaped cross section on one side in a side view, bulging from the outer edge portion of the shower head 30 toward the side wall of the processing container 11. A plurality of slits are provided in a C-shaped bottom surface portion of the outer peripheral ring 51. The outer peripheral ring 52 is an annular flat plate provided with a plurality of slits, and is placed on a C-shaped bottom surface portion of the outer peripheral ring 51.

As a result, the outer peripheral ring 52 functions as a protective member that protects the slit portion of the outer peripheral ring 51. The detailed configurations of the outer peripheral rings 51 and 52 will be described later.

A pressure gauge 71 capable of measuring the pressure in the C-shaped space surrounded by the outer peripheral ring 52 is provided near the upper portion of the processing container 11.

An adjustment plate 53 is provided below the outer peripheral rings 51 and 52 so as to face the C-shaped bottom surface portion of the outer peripheral ring 51. The adjustment plate 53 is configured to be movable up and down by a motor (not illustrated) or the like according to the pressure in the C-shaped space of the outer peripheral ring 52 measured by the pressure gauge 71.

A plasma containment mechanism 50 includes the outer peripheral rings 51 and 52, the adjustment plate 53, the motor (not illustrated) that moves the adjustment plate 53 up and down, and the like. Further, the configuration including the outer peripheral rings 51 and 52 may be referred to as an outer peripheral ring set. The outer peripheral rings 51 and 52 and the adjustment plate 53 included in the plasma containment mechanism 50 are made of, for example, silicon or quartz.

However, the outer peripheral rings 51 and 52 and the adjustment plate 53 may be made of silicon carbide, glassy carbon, tungsten, aluminum, or the like, and in the case of being made of a metal such as tungsten or aluminum, may have a coating of these metal oxides, or may be a ceramic of these metals.

A gas exhaust port 14 is provided in the processing container 11 further below the adjustment plate 53. A vacuum pump 72 is connected to the gas exhaust port 14. The configuration including the gas exhaust port 14 and the vacuum pump 72 may be referred to as an exhaust unit that exhausts the atmosphere in the processing container 11.

At the time of plasma processing of the wafer 10, the wafer 10 to be processed is placed on the wafer stage 20. In addition, the inside of the processing container 11 is evacuated via the outer peripheral rings 51 and 52 each having a plurality of slits by the vacuum pump 72 connected to the gas exhaust port 14. When the inside of the processing container 11 reaches a predetermined pressure, a processing gas is supplied from a gas supply device (not illustrated) to the wafer 10 on the wafer stage 20 via the gas flow path 32 of the shower head 30.

In addition, in the lower application type device, a radio frequency is applied to the wafer stage 20 as the lower electrode in a state where the shower head 30 as the upper electrode is grounded, and plasma is generated in the space between the shower head 30 and the wafer stage 20. On the lower electrode side, a potential gradient is generated between the plasma and the wafer 10 due to self-bias by the radio frequency voltage, ions in the plasma are accelerated to the wafer stage 20, and anisotropic etching processing is performed.

During the plasma processing, the plasma is preferably generated between the shower head 30 and the wafer stage 20 and directly above the wafer 10. However, the plasma generated between the shower head 30 and the wafer stage 20 tends to spread from the outer peripheral portion of the wafer 10 to the C-shaped space portion of the outer peripheral ring 51.

The adjustment plate 53 is moved up and down based on the measurement result of the pressure gauge 71, and adjusts the pressure in the C-shaped space to be constant. As a result, the plasma is suppressed from spreading to the outer peripheral portion of the wafer 10, and the plasma can be confined exclusively in the space between the shower head 30 and the wafer stage 20.

The narrower the separation distance between the adjustment plate 53 and the outer peripheral ring 52, the higher the plasma containment effect and the higher the plasma density. On the other hand, as the separation distance between the adjustment plate 53 and the outer peripheral ring 52 is larger, the plasma containment effect tends to be weakened and the plasma density tends to decrease.

A control unit 100 is configured as a computer including a central processing unit (CPU), a read only memory (ROM), a random access memory (RAM), and the like (not illustrated).

However, the control unit 100 may be configured as an application specific integrated circuit (ASIC) or the like having a function for use in the plasma processing apparatus 1.

The control unit 100 controls each unit of the plasma processing apparatus 1. That is, the control unit 100 controls each unit of the plasma processing apparatus 1 such as the wafer stage 20, the radio frequency power supply 44, the adjustment plate 53, the gas supply device, and the vacuum pump 72 to enable the above plasma processing.

### Configuration Example of Outer Peripheral Ring

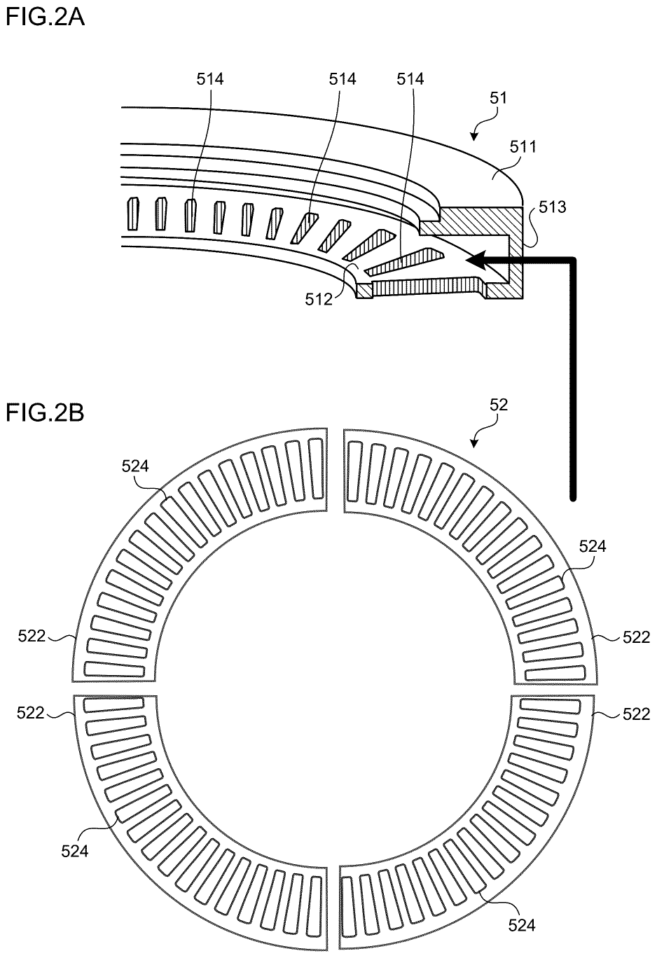

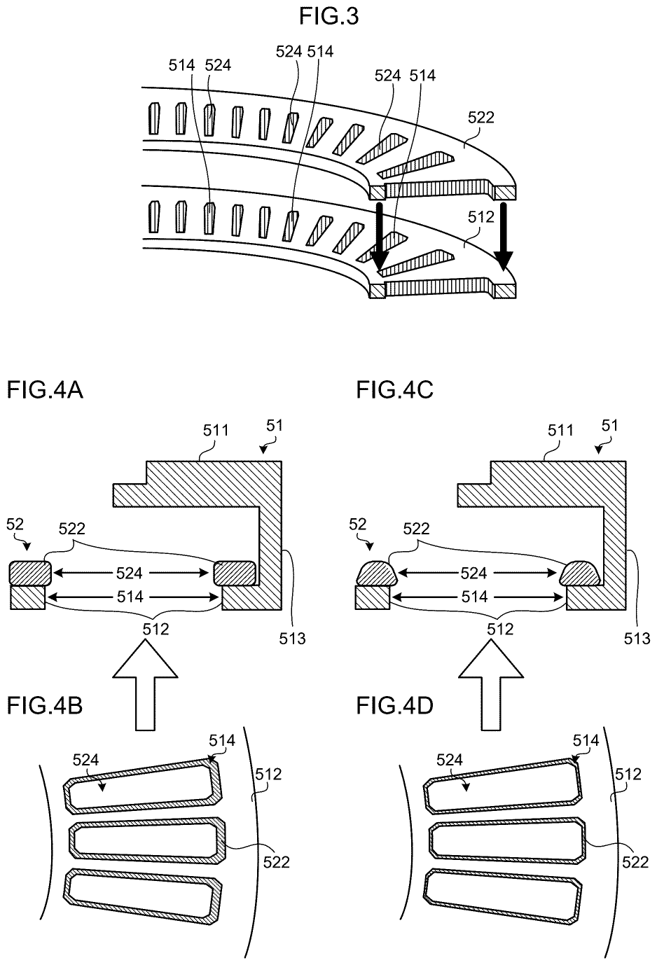

Next, a detailed configuration example of the outer peripheral rings 51 and 52 included in the plasma containment mechanism 50 will be described with reference to FIGS. 2A to 3.

FIGS. 2A and 2B are schematic views illustrating an example of configurations of the outer peripheral rings 51 and 52 according to the first embodiment. More specifically, FIG. 2A is a perspective cross-sectional view illustrating a part of the outer peripheral ring 51, and FIG. 2B is a top view illustrating an entire configuration of the outer peripheral ring 52.

As illustrated in FIG. 2A, the outer peripheral ring 51 includes annular portions 511 and 512, a wall portion 513, and a plurality of slits 514. The annular portions 511 and 512 are both formed in an annular and flat plate shape, and are disposed to face each other with a predetermined distance therebetween. The wall portion 513 is disposed so as to be orthogonal to the annular portions 511 and 512, and connects outer edge portions of these annular portions 511 and 512 to each other. As a result, the outer peripheral ring 51 is configured such that a cross-sectional shape of one side surface is a C-shape as a whole.

The annular portion 512 is installed in the processing container 11 of the plasma processing apparatus 1 so as to be positioned below the annular portion 511. The annular portion 512 has the plurality of slits 514. The plurality of slits 514 penetrate the annular portion 512 in the plate thickness direction, and are radially disposed toward the outer edge portion of the annular portion 512.

As illustrated in FIG. 2B, the outer peripheral ring 52 includes a plurality of divided members 522. These divided members 522 may have the same configuration, and are each configured in an arc shape and a flat plate shape. Each of the divided members 522 has a plurality of slits 524 penetrating the divided members 522 in the plate thickness direction. These divided members 522 are combined with each other to form the annular outer peripheral ring 52. In a state where the divided members 522 are combined in an annular shape, the plurality of slits 524 are disposed to radially extend toward the outer edge portion of the outer peripheral ring 52.

In the example of FIG. 2B, the outer peripheral ring 52 has four divided members 522. However, the number of the divided members 522 included in the outer peripheral ring 52 is not limited to four, and the outer peripheral ring 52 may include two, three, or five or more divided members 522.

As described above, since the outer peripheral ring 52 is divided into the plurality of divided members 522, each of the divided members 522 can be inserted into the C-shaped space between the annular portions 511 and 512 of the outer peripheral ring 51 and disposed on the upper surface of the annular portion 511 of the outer peripheral ring 51.

FIG. 3 is a perspective cross-sectional view illustrating a state in which the outer peripheral rings 51 and 52 according to the first embodiment overlap each other. FIG. 3 illustrates a portion of the annular portion 512 of the outer peripheral ring 51 and a corresponding portion of the divided member 522 of the outer peripheral ring 52.

As illustrated in FIG. 3, the plurality of slits 514 included in the annular portion 512 of the outer peripheral ring 51 and the plurality of slits 524 included in the divided members 522 of the outer peripheral ring 52 correspond to each other on a one-to-one basis, and are disposed so as to overlap each other in the vertical direction when the outer peripheral ring 52 is disposed on the outer peripheral ring 51. That is, the number of the slits 514 of the outer peripheral ring 51 is equal to the total number of the slits 524 of the outer peripheral ring 52.

In the plasma processing apparatus 1, the atmosphere in the processing container 11 is exhausted via the overlapping slits 514 and 524 of the outer peripheral rings 51 and 52.

FIGS. 4A to 4D are schematic cross-sectional views of one side surface of each of the outer peripheral rings 51 and 52 according to the first embodiment. More specifically, FIGS. 4A and 4B illustrate a cross section of one side surface of each of the new outer peripheral rings 51 and 52 immediately after being installed in the plasma processing apparatus 1, and a state in which each of the outer peripheral rings 51 and 52 is viewed from below. FIGS. 4C and 4D illustrate a cross section of one side surface of each of the outer peripheral rings 51 and 52 after a predetermined use time elapses, and a state in which each of the outer peripheral rings 51 and 52 is viewed from below.

As illustrated in FIG. 4A, initially, the slit 524 of the outer peripheral ring 52 is preferably configured to have an opening area smaller than the opening area of the slit 514 of the outer peripheral ring 51, for example. At this time, as illustrated in FIG. 4B, when the outer peripheral rings 51 and 52 are viewed from below, the inner edge portion of the slit 524 of the outer peripheral ring 52 should be seen protruding from the opening portion of the slit 514 of the outer peripheral ring 51.

As illustrated in FIG. 4C, after a predetermined use time elapses, the outer peripheral ring 52 is worn out by the plasma, and the opening area of the slit 524 becomes larger than the initial opening area. Therefore, as illustrated in FIG. 4D, when the outer peripheral rings 51 and 52 are viewed from below, the protruding portion of the inner edge portion of the slit 524 of the outer peripheral ring 52 from the opening portion of the slit 514 of the outer peripheral ring 51 decreases.

However, at the timing of FIGS. 4C and 4D, the outer peripheral ring 51 is protected by the outer peripheral ring 52, and the outer peripheral ring 51 is not worn out by plasma. By disposing the outer peripheral ring 52 in this manner, the wear of the outer peripheral ring 51 can be suppressed.

In addition, when the outer peripheral ring 52 is replaced with a new one at the timing of FIGS. 4C and 4D before the opening area of the slit 524 of the outer peripheral ring 52 becomes equal to or more than the opening area of the slit 514 of the outer peripheral ring 51, the wear of the outer peripheral ring 51 due to plasma can be further suppressed.

### Overview

In the plasma processing apparatus, in order to contain the spread of the plasma in the outer peripheral portion of the wafer, a C-shaped outer peripheral ring having a slit in the bottom surface and an adjustment plate capable of adjusting a separation distance with respect to the outer peripheral ring may be used. However, when the outer peripheral ring is worn out by the plasma, the opening area of the slit increases, and the plasma containment effect is deteriorated. As a result, plasma processing characteristics of the wafer fluctuate, which may lead to a decrease in yield of the semiconductor device. In addition, in order to maintain the plasma containment effect, it is necessary to replace the outer peripheral ring every time a predetermined use time elapses, which increases the manufacturing cost of the semiconductor device.

The plasma processing apparatus 1 according to the first embodiment includes the outer peripheral ring 51 including the annular portion 512 having the plurality of slits 514, the annular portion 511 facing the annular portion 512 at a predetermined distance, and the wall portion 513 connecting the outer edge portion of the annular portion 512 and the outer edge portion of the annular portion 511, and the outer peripheral ring 52 disposed on the surface of the annular portion 512 facing the annular portion 511 and having the plurality of slits 514 at positions overlapping the plurality of slits 524 in the vertical direction. As a result, it is possible to suppress the wear of the outer peripheral ring 51 and to stably contain the plasma over a long period of time.

According to the plasma processing apparatus 1 of the first embodiment, the number of the plurality of slits 524 of the outer peripheral ring 52 is equal to the number of the plurality of slits 514 of the outer peripheral ring 51. In this manner, by making the slits 514 and 524 of the outer peripheral rings 51 and 52 correspond to each other on a one-to-one basis, it is possible to more reliably suppress the expansion of the slit 514 due to the wear of the outer peripheral ring 51.

According to the plasma processing apparatus 1 of the first embodiment, the opening area of each of the plurality of slits 524 of the outer peripheral ring 52 is smaller than the opening area of each of the plurality of slits 514 of the outer peripheral ring 51. As a result, even when the slit 524 of the outer peripheral ring 52 expands after a predetermined use time elapses, the expansion of the slit 514 due to the wear of the outer peripheral ring 51 can be more reliably suppressed.

According to the plasma processing apparatus 1 of the first embodiment, the outer peripheral ring 52 includes the plurality of divided members 522 combined with each other to form an annular shape. As a result, the outer peripheral ring 52 can be easily disposed in the C-shaped space of the outer peripheral ring 51.

### Modification Example

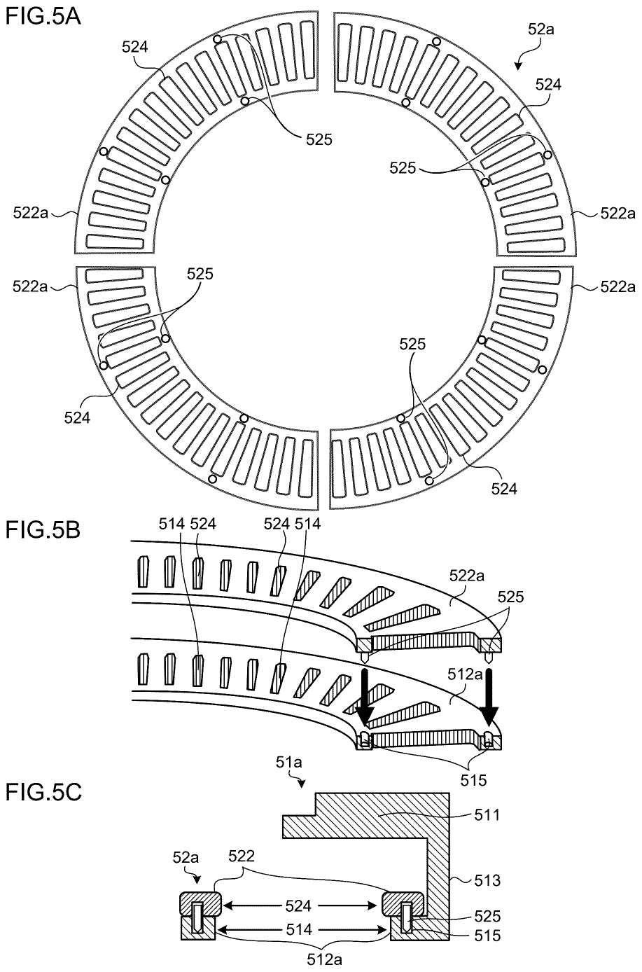

Next, a plasma processing apparatus according to a modification example of the first embodiment will be described with reference to FIGS. 5A to 7. The plasma processing apparatus according to the modification example is different from the plasma processing apparatus according to the first embodiment described above in that the outer peripheral rings 51a to 51c and 52a are configured to be fixed to each other.

In the following drawings, the same reference numerals are given to the same configurations as those of the above-described first embodiment, and the description thereof may be omitted.

FIGS. 5A to 5C are schematic views illustrating an example of configurations of outer peripheral rings 51a and 52a according to a modification example of the first embodiment. More specifically, FIG. 5A is a bottom view illustrating an entire configuration of the outer peripheral ring 52a. FIG. 5B is a perspective cross-sectional view illustrating a state in which the outer peripheral rings 51a and 52a overlap each other. FIG. 5C is a cross-sectional view of one side surface of the outer peripheral rings 51a and 52a.

As illustrated in FIG. 5A, at least one or more pins 525 are provided on a lower surface of each of a plurality of divided members 522a of the outer peripheral ring 52a, that is, a surface facing the outer peripheral ring 51a. In the example of FIG. 5A, each of the divided members 522 includes two pins 525 disposed at equal intervals on the inner edge portion and two pins 525 disposed at equal intervals on the outer edge portion at positions facing the two pins 525 of the inner edge portion. However, the number and arrangement of the pins 525 included in each divided member 522 are not limited to the example of FIG. 5A.

As illustrated in FIGS. 5B and 5C, a plurality of insertion holes 515 are provided on the upper surface of the annular portion 512a of the outer peripheral ring 51a, that is, on the surface facing the outer peripheral ring 52a, at positions facing the plurality of pins 525 of the outer peripheral ring 52a. When the outer peripheral ring 52a overlaps the annular portion 512a of the outer peripheral ring 51a, the plurality of pins 525 of the outer peripheral ring 52a are respectively inserted into the corresponding insertion holes 515 of the outer peripheral ring 51a, whereby the outer peripheral rings 51a and 52a are fixed to each other. Further, when the outer peripheral ring 51a is attached to the outer peripheral ring 52a, positioning between the outer peripheral rings 51a and 52a is facilitated.

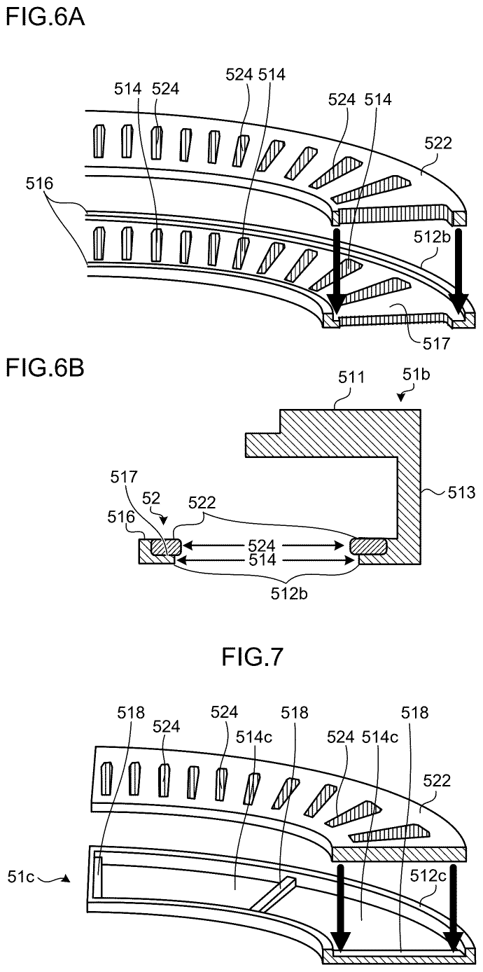

FIGS. 6A and 6B are schematic views illustrating another example of the configurations of outer peripheral rings 51b and 52 according to the modification example of the first embodiment. More specifically, FIG. 6A is a perspective cross-sectional view illustrating a state in which the outer peripheral rings 51b and 52 overlap each other. FIG. 6B is a cross-sectional view of one side surface of the outer peripheral rings 51b and 52.

In the example illustrated in FIGS. 6A and 6B, the outer peripheral ring 52 of the first embodiment described above is used together with the outer peripheral ring 51b of the modification example.

As illustrated in FIG. 6A, the annular portion 512b of the outer peripheral ring 51b is provided with a plurality of slits 514, and the surface facing the outer peripheral ring 52 on which the outer peripheral ring 52 is placed is an annular groove 517 recessed with respect to the inner edge portion and the outer edge portion of the outer peripheral ring 51b. At this time, the depth of the groove 517 of the annular portion 512b is substantially equal to the thickness of the outer peripheral ring 52, for example. Meanwhile, the inner edge portion and the outer edge portion of the outer peripheral ring 51 each have a protrusion 516 protruding annularly with respect to the groove 517.

The outer peripheral ring 52 is disposed to fit into the above-described groove 517 of the outer peripheral ring 51b. At this time, the upper surface of the outer peripheral ring 52 is substantially equal to the height of the upper surface of the protrusion 516 of the outer peripheral ring 51b. As a result, the outer peripheral rings 51b and 52 are fixed to each other. In addition, the outer peripheral rings 51b and 52 can be easily positioned. In addition, since the upper surface of the protrusion 516 of the outer peripheral ring 51b and the upper surface of the outer peripheral ring 52 have the same height, it is possible to adopt a configuration without having a protrusion or the like that can be a factor of disturbing the plasma, and it is possible to suppress the influence of these outer peripheral rings 51b and 52 on the plasma.

As illustrated in FIG. 6B, the protrusion 516 on the inner edge portion side of the protrusion 516 of the annular portion 512b of the outer peripheral ring 51b may be eliminated to have the same height as the bottom surface of the groove 517. In this case, the inner edge portion end of the outer peripheral ring 52 may be further widened to be equal to or more than the inner edge portion end of the outer peripheral ring 51b. However, in this case, it may be difficult to position the inner edge side of the outer peripheral ring 52 and the outer peripheral ring 51b. Therefore, for the positioning, the pin 525 and the insertion hole 515 may be provided only at the inner edge portion as illustrated in FIGS. 5A to 5C. As a result, the positions of the outer peripheral ring 52 and the outer peripheral ring 51b on the inner edge side can be determined.

FIG. 7 is a schematic view illustrating still another example of the configurations of the outer peripheral rings 51c and 52 according to the modification example of the first embodiment. More specifically, FIG. 7 is a perspective cross-sectional view illustrating a state in which the outer peripheral rings 51c and 52 overlap each other.

Also in the example illustrated in FIG. 7, the outer peripheral ring 52 of the first embodiment described above is used together with the outer peripheral ring 51c of the modification example.

As illustrated in FIG. 7, the annular portion 512c of the outer peripheral ring 51c has a plurality of slits 514c having an opening area larger than the opening area of each slit 524 of the outer peripheral ring 52. These slits 514c are separated by a plurality of spokes 518 radially extending from the inner edge portion to the outer edge portion of the annular portion 512c.

As a result, the plurality of slits 514c included in the annular portion 512c of the outer peripheral ring 51c is configured to have a fan-shaped opening shape. The plurality of slits 514c of the annular portion 512c correspond to several slits 524 adjacent to each other among the plurality of slits 524 of the outer peripheral ring 52. That is, these several slits 524 are disposed so as to overlap one slit 514c of the outer peripheral ring 51.

As described above, the annular portion 512c of the outer peripheral ring 51c is formed in a frame shape in which the outer peripheral ring 52 can be fitted as a whole. At this time, the plurality of spokes 518 of the annular portion 512c support the outer peripheral ring 52 disposed on the annular portion 512c from the lower surface. By fitting the outer peripheral ring 52 in the frame of the annular portion 512c in this manner, the outer peripheral rings 51c and 52 are fixed to each other. In addition, the outer peripheral rings 51c and 52 can be easily positioned.

According to the plasma processing apparatus of the modification example, the outer peripheral ring 52a has the pin 525 protruding from the surface of the outer peripheral ring 51a facing the annular portion 512a, and the annular portion 512a of the outer peripheral ring 51a has the insertion hole 515 into which the pin 525 of the outer peripheral ring 52a can be inserted on the surface facing the outer peripheral ring 52a.

As a result, the outer peripheral ring 52a can be more accurately positioned and fixed with respect to the outer peripheral ring 51a. By fixing the outer peripheral rings 51a and 52a to each other, it is possible to suppress the occurrence of positional deviation between the outer peripheral rings 51a and 52a during the operation of the plasma processing apparatus of the modification example.

According to the plasma processing apparatus of another example of the modification example, in the annular portion 512b of the outer peripheral ring 51b, the surface facing the outer peripheral ring 52 is the annular groove 517 recessed from the inner edge portion and the outer edge portion of the annular portion 512b, and the outer peripheral ring 52 can be fitted into the groove 517 of the outer peripheral ring 51b.

Even with such a configuration, the outer peripheral ring 52 can be positioned and fixed with respect to the outer peripheral ring 51b. In addition, since the surface of the outer peripheral ring 51b provided with the slit 514 is recessed as the groove 517, the shielding effect from the plasma is enhanced, and the expansion of the slit 514 can be further suppressed.

According to the plasma processing apparatus of another example of the modification example, the thickness of the outer peripheral ring 52 is substantially equal to the depth of the groove 517 included in the annular portion 512b of the outer peripheral ring 51b. As a result, when the outer peripheral ring 52 is fitted into the groove 517 of the outer peripheral ring 51b, irregularities do not occur on the surfaces of these members, and the influence on plasma can be suppressed.

According to the plasma processing apparatus of still another example of the modification example, the number of the plurality of slits 524 of the outer peripheral ring 52 is larger than the number of the plurality of slits 514c of the outer peripheral ring 51c, and two or more slits 524 of the plurality of slits 524 are disposed at positions overlapping one slit 514c of the plurality of slits 514c of the outer peripheral ring 51c.

Also with such a configuration, the outer peripheral ring 52 can be positioned and fixed with respect to the outer peripheral ring 51c. In addition, since the configuration is simple without the slit 514 and the like, the cost of the outer peripheral ring 51c can be reduced.

According to the plasma processing apparatus of these modification examples, other effects similar to those of the plasma processing apparatus 1 of the above-described embodiment are obtained.

### Second Embodiment

Hereinafter, a second embodiment will be described in detail with reference to the drawings. A plasma processing apparatus according to a second embodiment is different from the plasma processing apparatus according to the first embodiment described above in that a flat outer peripheral ring is disposed on a lower surface of a C-shaped outer peripheral ring.

In the following drawings, the same reference numerals are given to the same configurations as those of the above-described first embodiment, and the description thereof may be omitted.

### Configuration Example of Plasma Processing Apparatus

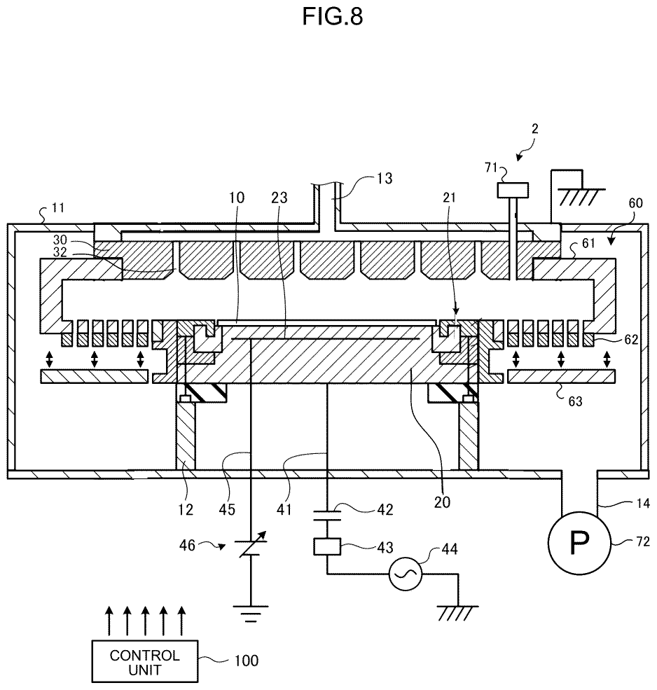

FIG. 8 is a cross-sectional view schematically illustrating an example of a configuration of a plasma processing apparatus 2 according to the second embodiment. The plasma processing apparatus 2 includes a plasma containment mechanism 60 instead of the plasma containment mechanism 50 of the first embodiment described above.

The plasma containment mechanism 60 includes outer peripheral rings 61 and 62, an adjustment plate 63, a motor (not illustrated) that drives the adjustment plate 63, and the like. The outer peripheral ring 61 has a C-shaped cross-sectional shape as a shape of one side surface. The outer peripheral ring 62 is disposed on a lower surface of the outer peripheral ring 61. The adjustment plate 63 faces the outer peripheral ring 62 and is configured to be capable of adjusting a separation distance with respect to the outer peripheral ring 62.

### Configuration Example of Outer Peripheral Ring

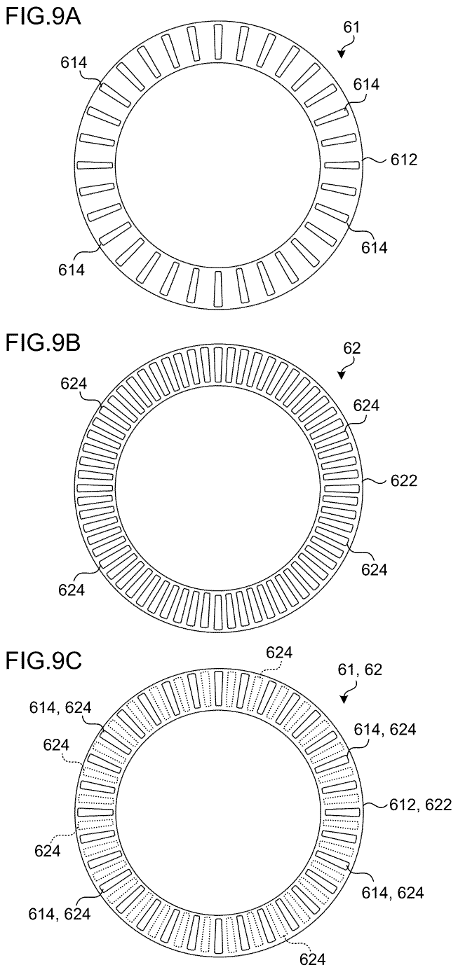

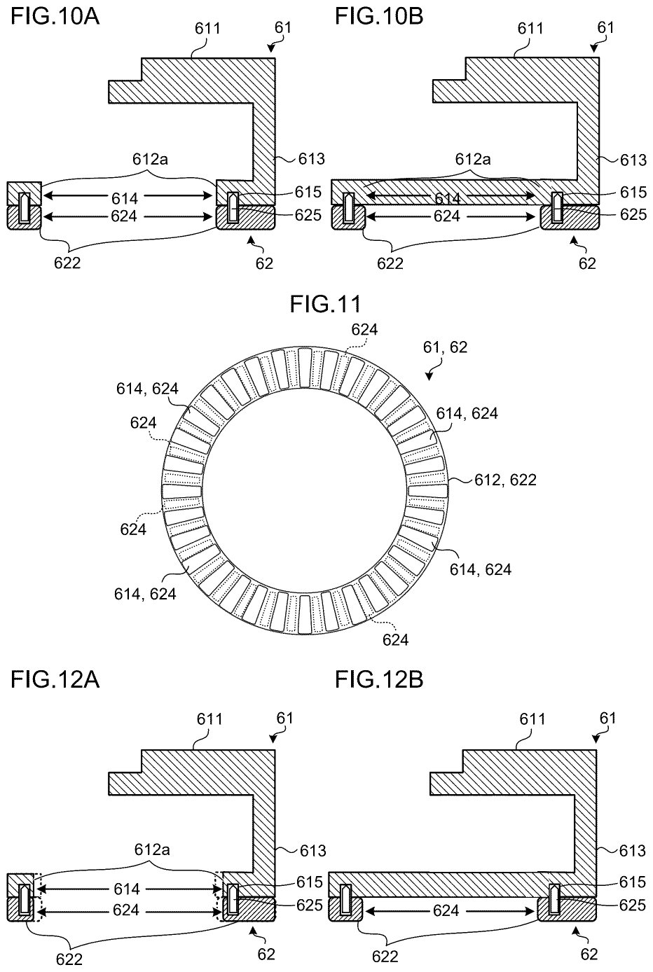

Next, a detailed configuration example of the outer peripheral rings 61 and 62 included in the plasma containment mechanism 60 will be described with reference to FIGS. 9A to 10B.

FIGS. 9A to 10B are schematic views illustrating examples of configurations of the outer peripheral rings 61 and 62 according to the second embodiment.

More specifically, FIG. 9A is a top view illustrating an annular portion 612 of the outer peripheral ring 61, FIG. 9B is a top view illustrating the entire configuration of the outer peripheral ring 62, and FIG. 9C is a top view illustrating a state in which the outer peripheral rings 61 and 62 overlap each other.

FIG. 10A is a cross-sectional view of one side surface of the outer peripheral rings 61 and 62, and illustrates a cross section of the slit 624 of the slits 624 of the outer peripheral ring 62 overlapping the slits 614 of the outer peripheral ring 61. FIG. 10B is a cross-sectional view of one side surface of the outer peripheral rings 61 and 62, and illustrates a cross section of the slit 624 of the slits 624 of the outer peripheral ring 62 not overlapping the slits 614.

As illustrated in FIG. 9A, the outer peripheral ring 61 has an annular portion 612 formed in an annular and flat plate shape. The annular portion 612 is provided with the plurality of slits 614 penetrating the annular portion 612 in the plate thickness direction and disposed radially toward the outer edge portion of the annular portion 612. Other configurations of the outer peripheral ring 61 are similar to those of the first embodiment described above.

As illustrated in FIG. 9B, the outer peripheral ring 62 includes an annular member 622 formed in an annular and flat plate shape. The annular member 622 is provided with the plurality of slits 624 penetrating the annular member 622 in the plate thickness direction and disposed radially toward the outer edge portion of the annular member 622.

The number of the slits 624 of the outer peripheral ring 62 is, for example, twice the number of the slits 614 of the outer peripheral ring 61. Thus, the plurality of slits 624 are more densely disposed than the plurality of slits 614, and the spacing between each other is about ½ of the plurality of slits 614.

As illustrated in FIG. 9C, when the outer peripheral ring 62 overlaps the annular portion 612 of the outer peripheral ring 61, every other slit 624 out of the plurality of slits 624 of the outer peripheral ring 62 overlaps each slit 614 of the outer peripheral ring 61 in the vertical direction. That is, half of the plurality of slits 624 overlap any of the plurality of slits 614, and the remaining half does not overlap any of the slits 614.

In FIG. 9C, the slits 624 of the outer peripheral ring 62 that do not overlap the slits 614 of the outer peripheral ring 61 are indicated by a broken line.

As illustrated in FIGS. 10A and 10B, the outer peripheral ring 61 includes, in addition to the annular portion 612 described above, the annular portion 611 facing the annular portion 612 with a predetermined distance therebetween, and the wall portion 613 connecting the annular portion 611 and the annular portion 612.

At least one or more screws 625 is provided on the upper surfaces of the plurality of annular members 622 of the outer peripheral ring 62, that is, the surface facing the outer peripheral ring 61. The number and arrangement of these screws 625 of the outer peripheral ring 62 may be similar to, for example, the pins 525 included in the outer peripheral ring 52a of FIGS. 5A to 5C illustrated in the modification example of the first embodiment described above. Alternatively, the number and arrangement of these screws 625 may be different from the pins 525 of FIGS. 5A-5C described above.

On the lower surface of the annular portion 612 of the outer peripheral ring 61, that is, the surface facing the outer peripheral ring 62, a plurality of insertion holes 615 are provided at positions facing the plurality of screws 625 of the outer peripheral ring 62.

When the outer peripheral ring 62 overlaps the annular portion 612 of the outer peripheral ring 61, the plurality of screws 625 of the outer peripheral ring 62 are respectively inserted into the corresponding insertion holes 615 of the outer peripheral ring 61, whereby the outer peripheral ring 62 can be attached to the lower surface of the outer peripheral ring 61.

As illustrated in FIG. 10A, the opening areas of the slits 614 and 624 of the outer peripheral rings 61 and 62 are substantially equal, and in a state where any one of the slits 624 of the outer peripheral ring 62 overlaps the corresponding slit 614 of the outer peripheral ring 61, the outer shapes thereof are substantially matched.

As illustrated in FIG. 10B, at a position where the slits 614 and 624 of the outer peripheral rings 61 and 62 do not overlap each other in the vertical direction, the slit 624 of the outer peripheral ring 62 is closed by the annular portion 612 of the outer peripheral ring 61.

In the plasma processing apparatus 2 of the second embodiment, the atmosphere in the processing container 11 is exhausted via the slit 624 overlapping the slit 614 of the outer peripheral ring 61 and the slit 614 corresponding to the slit 624, among the plurality of slits 624 of the outer peripheral ring 62.

### Usage Example of Outer Peripheral Ring

Next, a usage example of the outer peripheral rings 61 and 62 of the second embodiment will be described with reference to FIGS. 11 to 15B.

FIG. 11 is a top view illustrating the entire configuration of the outer peripheral rings 61 and 62 according to the second embodiment after a predetermined use time has elapsed.

As illustrated in FIG. 11, the outer peripheral rings 61 and 62 after being used in the plasma processing apparatus 2 for a predetermined time are worn out by being exposed to plasma for a predetermined time. Therefore, the opening areas of the plurality of slits 614 of the outer peripheral ring 61 are all enlarged. Similarly, among the plurality of slits 624 of the outer peripheral ring 62, the opening area of the slit 624 vertically overlapping the slit 614 of the outer peripheral ring 61 is also enlarged.

Meanwhile, as indicated by a broken line in FIG. 11, the slits 624 which are disposed alternately with respect to the slit 624 enlarged as described above and do not vertically overlap the slit 614 of the outer peripheral ring 61 are in a state of being covered with the annular portion 612 of the outer peripheral ring 61 in the plasma processing apparatus 2, and thus, are hardly worn out by the plasma, and substantially maintain the opening area of the initial opening area of a new product.

FIGS. 12A and 12B are cross-sectional views of one side surfaces of the outer peripheral rings 61 and 62 according to the second embodiment after a lapse of a predetermined use time.

More specifically, FIG. 12A illustrates a cross section of the slits 624 vertically overlapping the slits 614 of the outer peripheral ring 61, among the slits 624 of the outer peripheral ring 62. FIG. 12B illustrates a cross section of the slits 624 not overlapping the slits 614, among the slits 624 of the outer peripheral ring 62.

As illustrated in FIG. 12A, at the position where the slits 614 and 624 of the outer peripheral rings 61 and 62 overlap each other, the opening area of each of the slits 614 and 624 is enlarged due to the wear by plasma.

As illustrated in FIG. 12B, at a position where the slit 624 of the outer peripheral ring 62 does not overlap the slit 614 of the outer peripheral ring 61, the slit 624 of the outer peripheral ring 62 is protected by the annular portion 612 of the outer peripheral ring 61, and the opening area of the slit 624 of the outer peripheral ring 62 hardly increases.

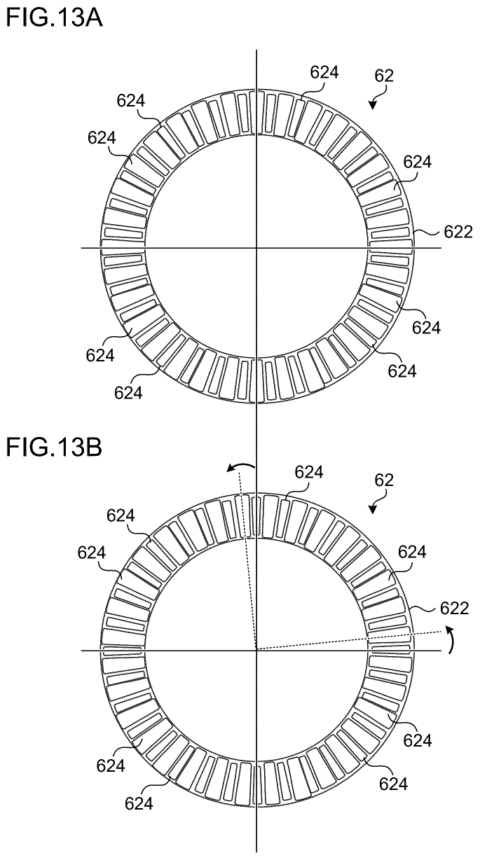

FIGS. 13A and 13B are top views illustrating the entire configuration of the outer peripheral ring 62 according to the second embodiment after a predetermined use time has elapsed.

As illustrated in FIG. 13A, and as described above, since every other slit 624 of the plurality of slits 624 of the outer peripheral ring 62 overlaps the slit 614 of the outer peripheral ring 61 in the vertical direction, the opening area is enlarged due to the wear by plasma. Meanwhile, since every other slit 624 disposed between the slits 624 is protected by the outer peripheral ring 61, there is no wear due to plasma, and the opening area hardly increases.

In the plasma processing apparatus 2 of the second embodiment, after a predetermined use time has elapsed, the outer peripheral ring 62 in the above-described state is once detached from the outer peripheral ring 61, and is rotated by a predetermined angle around a center point viewed from the upper surface of the outer peripheral ring 62 as a rotation axis, and is attached to the outer peripheral ring 61 again. In the state of being attached to the plasma processing apparatus 2, the center point of the outer peripheral ring 62 serving as the rotation axis of the outer peripheral ring 62 substantially coincides with the center point in the plane of the wafer stage 20.

As illustrated in FIG. 13B, by rotating the outer peripheral ring 62 by a predetermined angle, the plurality of slits 624 originally located at positions overlapping the slits 614 of the outer peripheral ring 61 in the vertical direction move to positions not overlapping the slits 614 of the outer peripheral ring 61. Meanwhile, the remaining slits 624 that were originally at positions not overlapping the slits 614 of the outer peripheral ring 61 in the vertical direction move to positions overlapping any of the slits 614 of the outer peripheral ring 61.

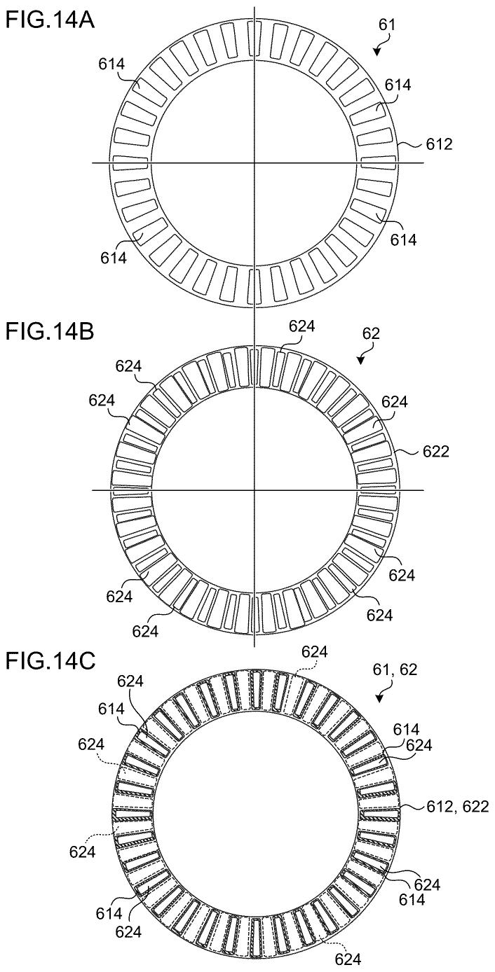

FIGS. 14A to 14C are top views illustrating a state where the outer peripheral rings 61 and 62 according to the second embodiment are overlapped while changing the angle after a predetermined use time elapses. More specifically, FIG. 14A illustrates the overall top surface of the outer peripheral ring 61, FIG. 14B illustrates the overall top surface of the outer peripheral ring 62, and FIG. 14C illustrates the overall top surfaces of the outer peripheral rings 61 and 62 overlap each other.

As illustrated in FIG. 14B, by rotating the outer peripheral ring 62 by a predetermined angle from the initial attached state, the plurality of slits 624 that has been protected from plasma up to this point at positions not overlapping the slits 614 of the outer peripheral ring 61 and has an opening area that is hardly increased are disposed at positions corresponding to the slits 614 of the outer peripheral ring 61 illustrated in FIG. 14A.

As illustrated in FIG. 14C, when the outer peripheral ring 61 in FIG. 14A and the outer peripheral ring 62 in FIG. 14B overlap each other, the slit 614 in which the opening area of the outer peripheral ring 62 is hardly enlarged is disposed on the bottom surface of any of the plurality of slits 624 of the outer peripheral ring 61. When these outer peripheral rings 61 and 62 are viewed from above, the inner edge portion of the slit 624 of the outer peripheral ring 62 should protrude from the opening portion of any slit 614 of the outer peripheral ring 61.

In this manner, after a predetermined use time has elapsed, the outer peripheral ring 62 is rotated by a predetermined angle and attached again to the outer peripheral ring 61, whereby the opening area of the enlarged slit 614 of the outer peripheral ring 61 is corrected to an opening area substantially equal to the initial opening area of the new product by the slit 624 of the outer peripheral ring 62 which is hardly enlarged.

The use time of the outer peripheral rings 61 and 62 before the rotation of the outer peripheral ring 62 can be, for example, a time before the containment characteristics of the plasma become unstable due to the wear of the outer peripheral rings 61 and 62. It can also be said that the above-described use time of the outer peripheral rings 61 and 62 is a time when the outer peripheral ring 61 reaches the lifetime, for example, when the outer peripheral ring 61 is used alone.

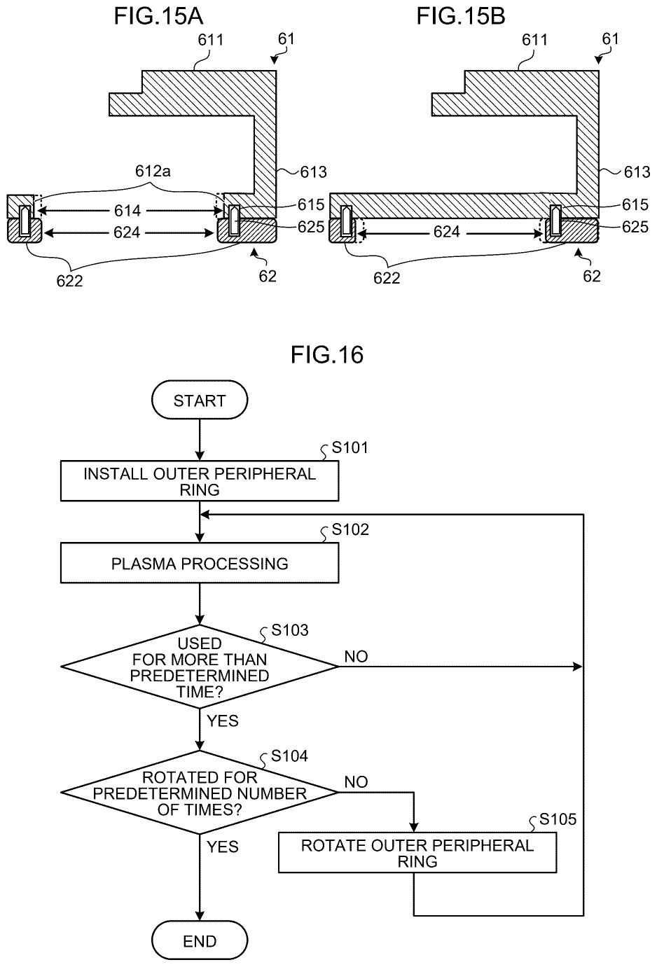

FIGS. 15A and 15B are cross-sectional views of one side surfaces after the outer peripheral rings 61 and 62 according to the second embodiment are reattached.

More specifically, FIG. 15A illustrates a cross section of the slits 624 vertically overlapping the slits 614 of the outer peripheral ring 61, among the slits 624 of the outer peripheral ring 62. FIG. 15B illustrates a cross section of the slits 624 not overlapping the slits 614 vertically, among the slits 624 of the outer peripheral ring 62.

As illustrated in FIG. 15A, a new slit 624 of the outer peripheral ring 62 is disposed below each slit 614 of the outer peripheral ring 61. The slit 614 of the outer peripheral ring 61 has an opening area larger than the initial area by the plasma processing performed up to this point. However, the opening area of the new slit 624 of the outer peripheral ring 62 disposed below the slit 614 hardly increases. Therefore, as the outer peripheral rings 61 and 62 as a whole, the opening area of the slit 614, 624 substantially maintains the original opening area of the new outer peripheral ring.

As illustrated in FIG. 15B, the slit 624 enlarged by the wear of the outer peripheral ring 62 is disposed at a position not overlapping the slit 614 of the outer peripheral ring 61.

After the rotation of the outer peripheral ring 62, the atmosphere in the processing container 11 is exhausted via the slit 624 newly overlapping the slit 614 of the outer peripheral ring 61 among the plurality of slits 624 of the outer peripheral ring 62 and the slit 614 corresponding to the slit 624.

### Example of Plasma Processing

Next, an example of plasma processing of the wafer 10 in the plasma processing apparatus 2 according to the second embodiment will be described with reference to FIG. 16. The processing of the wafer 10 in the plasma processing apparatus 2 is performed, for example, as a part of the manufacturing process of the semiconductor device.

FIG. 16 is a flowchart illustrating an example of a procedure of plasma processing in the plasma processing apparatus 2 according to the second embodiment.

As illustrated in FIG. 16, new outer peripheral rings 61 and 62 are attached to the plasma processing apparatus 2 (Step S101), and plasma processing is performed on a predetermined number of wafers 10 (Step S102). While the use time of the outer peripheral rings 61 and 62 is less than the predetermined time (Step S103: No), the plasma processing on the wafer 10 is continued (Step S102).

The use time of the outer peripheral rings 61 and 62 is determined by integrating the plasma generation time based on, for example, the operating time of the radio frequency power supply 44 included in the plasma processing apparatus 2. The plasma generation integration time is also called a Resonance Frequency (RF) integration time or the like.

When the use time of the outer peripheral rings 61 and 62 is equal to or more than the predetermined time (Step S103: Yes), in a case where the number of rotations of the outer peripheral ring 62 currently in use has not reached the predetermined number (Step S104: No), the outer peripheral ring 62 is rotated by a predetermined angle from the initial attachment angle and attached again to the outer peripheral ring 61 (Step S105), and the plasma processing on the wafer 10 is continued (Step S102).

When the outer peripheral ring 62 in use has already been rotated a predetermined number of times (Step S104: Yes), the use of the outer peripheral ring 62 is stopped and the outer peripheral ring 62 is replaced with a new outer peripheral ring.

In the example illustrated in FIGS. 9A to 15B described above, the outer peripheral ring 62 can be rotated only once during use, and is replaced when a predetermined use time is reached again after the rotation.

As described above, the plasma processing in the plasma processing apparatus 2 of the second embodiment ends.

### Overview

According to the method for manufacturing a semiconductor device of the second embodiment, the outer peripheral ring 61 including the annular portion 612 having the plurality of slits 614 disposed radially outward from the outer edge portion of the wafer stage 20, and the outer peripheral ring 62 disposed on the surface of the annular portion 612 opposite to the surface facing the annular portion 611 and having the plurality of slits 624 disposed radially outward from the outer edge portion of the wafer stage 20 and having a larger number of slits 624 than the plurality of slits 614 are used.

By using the plasma processing apparatus 2 including the outer peripheral rings 61 and 62, it is possible to suppress the wear of the outer peripheral rings 61 and 62 as a whole and to stably contain the plasma over a long period of time.

According to the method for manufacturing a semiconductor device of the second embodiment, the outer peripheral ring 62 is disposed at a predetermined angle with respect to the outer peripheral ring 61 with the center point in the plane of the wafer stage 20 as the rotation axis, the slits 624 as many as the plurality of slits 614 among the plurality of slits 624 overlap the plurality of slits 614 in the vertical direction, and plasma processing is performed on the wafer 10 placed on the wafer stage 20 in a state where the plurality of slits 614 and the same number of slits 624 are overlapped in the vertical direction.

As a result, during the above-described plasma processing, half of the slits 624 of the outer peripheral ring 62 are maintained without being exposed to the plasma. Therefore, it is possible to maintain half of the slits 624 of the outer peripheral ring 62 in a substantially new state while the predetermined use time elapses.

According to the method for manufacturing a semiconductor device of the second embodiment, when the plasma processing time reaches a predetermined time, the outer peripheral ring 62 is rotated so as to form a predetermined angle different from the above with respect to the outer peripheral ring 61 with the center point in the plane of the wafer stage 20 as the rotation axis, the new slits 624 as many as the plurality of slits 614 among the plurality of slits 624 overlap the plurality of slits 614 in the vertical direction, and the plasma processing is performed on the wafer placed on the wafer stage 20 in a state where the plurality of slits 614 and the new slits 624 overlap each other in the vertical direction.

As a result, the outer peripheral rings 61 and 62 can be used after the predetermined use time has elapsed and until the predetermined use time is reached. Therefore, in principle, the life of the outer peripheral rings 61 and 62 can be extended by 2 times as a whole.

In the second embodiment described above, it is assumed that the outer peripheral ring 62 is manually rotated and reattached to the outer peripheral ring 61. However, the outer peripheral ring 62 may be configured to be able to automatically rotate with respect to the outer peripheral ring 61 using a known technique using a gear, a motor, and the like.

In the first and second embodiments and the modification example described above, the plasma processing apparatus 1 is configured as an RIE apparatus, but the present invention is not limited thereto. The plasma processing apparatus may be an apparatus that performs plasma processing other than etching, such as a chemical dry etching (CDE) apparatus or a chemical vapor deposition (CVD) apparatus.

### Supplementary Note

Hereinafter, preferred aspects of the present invention will be additionally described.

### Supplementary Note 1

According to one aspect of the present invention,
there is provided a method for manufacturing a semiconductor device performed by a plasma processing apparatus including
a first outer peripheral ring that is
disposed on an outer periphery of a lower electrode facing an upper electrode in a processing container in which plasma processing is performed, and includes
a first annular portion having a plurality of first slits radially disposed outward from an outer edge portion of the lower electrode,
a second annular portion facing the first annular portion at a predetermined distance, and
a wall portion connecting an outer edge portion of the first annular portion and an outer edge portion of the second annular portion, and
a second outer peripheral ring that is
disposed on a surface of the first annular portion opposite to a surface facing the second annular portion, and has
a plurality of second slits disposed radially outward from the outer edge portion of the lower electrode and having a larger number of slits than the plurality of first slits, and
an exhaust unit that exhausts the inside of the processing container through the first and second outer peripheral rings, the method comprising:
disposing the second outer peripheral ring at a first angle with respect to the first outer peripheral ring with a center point in a plane of the lower electrode as a rotation axis, and overlapping third slits of the plurality of second slits as many as the plurality of first slits with the plurality of first slits in a vertical direction;
performing the plasma processing on a first substrate placed on the lower electrode in a state where the plurality of first slits and the third slits overlap each other in the vertical direction;
when time of the plasma processing reaches a predetermined time, rotating the second outer peripheral ring so as to form a second angle with respect to the first outer peripheral ring with the center point in the plane of the lower electrode as the rotation axis, and overlapping fourth slits of the plurality of second slits as many as the plurality of first slits with the plurality of first slits in the vertical direction; and
performing the plasma processing on a second substrate placed on the lower electrode in a state where the plurality of first slits and the fourth slits overlap each other in the vertical direction.

### Supplementary Note 2

In the method according to Supplementary Note 1,
the exhaust unit exhausts the inside of the processing container through second slits overlapping the plurality of first slits in the vertical direction, among the plurality of second slits.

### Supplementary Note 3

In the method according to Supplementary Note 1,
in a state where the second outer peripheral ring is disposed at the first angle with respect to the first outer peripheral ring, the inside of the processing container is exhausted by the exhaust unit via the plurality of first slits and the third slits, and
in a state where the second outer peripheral ring is disposed at the second angle with respect to the first outer peripheral ring, the inside of the processing container is exhausted by the exhaust unit via the plurality of first slits and the fourth slits.

### Supplementary Note 4

In the method according to Supplementary Note 1,
the plasma processing apparatus further includes an adjustment plate facing the second outer peripheral ring on a side opposite to the first annular portion, and
a separation distance of the adjustment plate from the second outer peripheral ring is adjusted according to a pressure of a space surrounded by the first annular portion and the second annular portion.

### Supplementary Note 5

According to another aspect of the present invention,
there is provided a plasma processing apparatus comprising:
a processing container in which a substrate is processed;
an upper electrode that supplies a processing gas into the processing container;
a lower electrode which is disposed in the processing container so as to face the upper electrode and on which the substrate is placed;
a power supply that supplies power to at least one of the upper electrode and the lower electrode and generates plasma in the processing container;
first and second outer peripheral rings that are disposed on an outer periphery of the lower electrode; and
an exhaust unit that exhausts the inside of the processing container via the first and second outer peripheral rings, in which
the first outer peripheral ring includes
a first annular portion that has a plurality of first slits,
a second annular portion that faces the first annular portion at a predetermined distance, and
a wall portion that connects an outer edge portion of the first annular portion and an outer edge portion of the second annular portion, and
the second outer peripheral ring includes a plurality of second slits that are disposed on either an upper or a lower surface of the first annular portion and provided at positions at which at least some second slits overlap the plurality of first slits in a vertical direction.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An outer peripheral ring set used in a plasma processing apparatus for processing a substrate, the outer peripheral ring set comprising:
a first outer peripheral ring including
a first annular portion that has a plurality of first slits,
a second annular portion that faces the first annular portion at a predetermined distance, and
a wall portion that connects an outer edge portion of the first annular portion and an outer edge portion of the second annular portion; and
a second outer peripheral ring that is disposed on a surface of the first annular portion facing the second annular portion and has a plurality of second slits at positions overlapping the plurality of first slits in a vertical direction.

2. The outer peripheral ring set according to claim 1, wherein
the plurality of first slits are radially disposed toward the outer edge portion of the first annular portion, and
the plurality of second slits are radially disposed toward an outer edge portion of the second outer peripheral ring.

3. The outer peripheral ring set according to claim 2, wherein
the number of the plurality of second slits is larger than the number of the plurality of first slits, and
two or more second slits of the plurality of second slits are disposed at positions overlapping one first slit of the plurality of first slits.

4. The outer peripheral ring set according to claim 2, wherein
the number of the plurality of second slits is equal to the number of the plurality of first slits.

5. The outer peripheral ring set according to claim 4, wherein
an opening area of each of the plurality of second slits is smaller than an opening area of each of the plurality of first slits.

6. The outer peripheral ring set according to claim 1, wherein
the second outer peripheral ring includes a pin protruding from a surface facing the first annular portion, and
the first annular portion includes an insertion hole, into which the pin is able to be inserted is provided, in a surface facing the second outer peripheral ring.

7. The outer peripheral ring set according to claim 6, wherein
the second outer peripheral ring includes a plurality of pins including the pin, each of which protrudes from a surface facing the first annular portion, and
the first annular portion includes a plurality of insertion holes including the insertion hole, into each of which the plurality of pins are able to be inserted, on a surface facing the second outer peripheral ring.

8. The outer peripheral ring set according to claim 1, wherein
in the first annular portion, a surface facing the second outer peripheral ring is an annular groove recessed from an inner edge portion of the first annular portion and the outer edge portion, and
the second outer peripheral ring is configured to be able to fit into the groove.

9. The outer peripheral ring set according to claim 8, wherein
a thickness of the second outer peripheral ring is equal to a depth of the groove.

10. The outer peripheral ring set according to claim 1, wherein
the second outer peripheral ring is configured to include a plurality of members combined with each other to form an annular shape.

11. The outer peripheral ring set according to claim 1, wherein
the plasma processing apparatus includes an adjustment plate facing a surface of the first annular portion opposite to the surface facing the second annular portion in a state where the first outer peripheral ring is attached to the plasma processing apparatus, and
the adjustment plate is configured so that a separation distance from the first annular portion is adjustable according to a pressure of a space surrounded by the first annular portion and the second annular portion.

12. A plasma processing apparatus comprising:
a processing container in which a substrate is processed;
an upper electrode that supplies a processing gas into the processing container;
a lower electrode which is disposed in the processing container so as to face the upper electrode and on which the substrate is placed;
a power supply that supplies power to at least one of the upper electrode and the lower electrode and generates plasma in the processing container;
first and second outer peripheral rings that are disposed on an outer periphery of the lower electrode; and
an exhaust unit that exhausts the inside of the processing container via the first and second outer peripheral rings, wherein
the first outer peripheral ring includes
a first annular portion that has a plurality of first slits,
a second annular portion that faces the first annular portion at a predetermined distance, and
a wall portion that connects an outer edge portion of the first annular portion and an outer edge portion of the second annular portion, and
the second outer peripheral ring includes a plurality of second slits that are disposed on an upper surface of the first annular portion and provided at positions overlapping the plurality of first slits in a vertical direction.
